(19) United States
(12) Patent Application Publication
(10) Pub. No.: US 2022/0005827 A1
(43) Pub. Date: Jan. 6, 2022

(54) TECHNIQUES FOR MANUFACTURING SPLIT-CELL 3D-NAND MEMORY DEVICES

(71) Applicant: Invensas Corporation, San Jose, CA (US)

(72) Inventors: Xu Chang, San Jose, CA (US); Belgacem Haba, Saratoga, CA (US); Rajesh Katkar, Milpitas, CA (US); David Edward Fisch, Pleasanton, CA (US); Javier A. Delacruz, San Jose, CA (US)

(21) Appl. No.: 17/362,557

(22) Filed: Jun. 29, 2021

Related U.S. Application Data
(60) Provisional application No. 63/048,342, filed on Jul. 6, 2020.

(51) Int. Cl. H01L 27/11582; H01L 27/11556

(52) U.S. Cl. CPC H01L 27/11582; H01L 27/11556

(57) ABSTRACT

Techniques for manufacturing memory devices, such as 3-dimensional NAND (3D-NAND) memory devices, may include splitting gate planes (e.g., the planes that include the word lines) into strips, thereby splitting the memory cells and increasing a density of memory cells for a respective memory device. The techniques described herein are applicable to various types of 3D-NAND or other memory devices.

### PRIORITY CLAIM AND CROSS-REFERENCE TO RELATED APPLICATIONS

This Application is a non-provisional of, and claims priority under 35 USC § 119(e), to U.S. Provisional Patent Application No. 63/048,342, filed, Jul. 6, 2020, which is fully incorporated by reference herein as if fully set forth below.

### BACKGROUND

NAND flash Memory is a type of non-volatile storage technology. NAND flash memory provides large storage capacity with quick access times and low power usage within a robust package, making it commonplace in many modem electronic devices, such as solid-state hard drives, smart phones, flash drives, memory cards, computers, etc. Conventional NAND flash has planar memory cell architecture and may also be termed as planar NAND. Three-dimensional (3D) NAND flash memory devices comprise memory cells stacked vertically using a charge trapping or floating gate flash architecture and may also be referred to as vertical NAND flash (VNAND). The vertical layers allow larger areal densities without requiring a larger footprint.

Generally, the density of memory cells is limited by the number of layers in a stack of the 3D-NAND memory device, as well as the area of the layers in the stack. Thus, the number of memory cells per the 3D-NAND memory device may be increased if the density of memory cells per layer is increased. In addition, density can be increased by storing multiple bits of data in each cell by varying the amount of charge stored in each cell.

### BRIEF DESCRIPTION OF THE DRAWINGS

The detailed description is set forth below with reference to the accompanying figures. In the figures, the left-most digit(s) of a reference number identifies the figure in which the reference number first appears. The use of the same reference numbers in different figures indicates similar or identical items. The systems depicted in the accompanying figures are not to scale and components within the figures may be depicted not to scale with respect to each other.

FIG. 1 is a perspective view of an example of 3D-NAND memory device.

FIGS. 2A-2Q schematically illustrate an example method of manufacturing 3D-NAND memory devices, such as the 3D-NAND memory device of FIG. 1.

FIGS. 3A-3J schematically illustrate another example method of manufacturing 3D-NAND memory devices, such as the 3D-NAND memory device of FIG. 1.

FIGS. 4A-4W schematically illustrate additional example methods of manufacturing 3D-NAND memory devices, such as the 3D-NAND memory device of FIG. 1.

FIG. 5 schematically illustrates a vertical channel of a 3D-NAND memory device with multiple memory cells in a hole of the vertical channel along gate planes.

FIG. 6 illustrates a flow diagram of an example method of manufacturing 3D-NAND memory devices, such as the 3D-NAND memory device of FIG. 1.

### DETAILED DESCRIPTION

### Overview

This disclosure describes example methods for manufacturing 3D-NAND memory devices. The methods allow for increasing (e.g., doubling) the memory cell densities within the 3D-NAND memory devices. In some examples, increases in memory cell density is accomplished at least in part by splitting the word planes, e.g., the planes that include the word lines, into long strips. The various methods described herein are applicable to various types of 3D-NAND memory devices.

In some examples, a method of making a 3D-NAND memory device may include defining a pipe connection within a substrate and a conductive material, such as polysilicon, may be used in the pipe connection. Layers may be deposited on the substrate. The layers may comprise alternating first layers comprising a first insulating material, such as a silicon oxide, oxy-nitride, carbo-nitride, etc., and second layers comprising a second material, such as, for example, polysilicon, or a metal such as, for example, tungsten. The first layers in this example serve as insulating layers. The second layers in this example serve as the word planes of the 3D-NAND memory device. Depending on the configuration, the second layers may initially comprise nitride that is eventually replaced with metal, as will be discussed further herein. The alternating layers generally provide a stack of layers. Depending on the configuration, the stack may include 24 to 256 or more layers to form memory cells within, although more or fewer layers may be included depending on the configuration. The stack may have a peripheral staircase region for electrical contacts to wordlines and selection signal lines.

Once the stack has been formed, a plurality of grooves may be etched within the stack. In some embodiments, the grooves may be etched through all of the layers in the stack and extend entirely through the staircase region. However, in other embodiments, some grooves may be etched through a majority of the layers leaving some layers at the bottom of the stack unetched and some grooves may only extend partially through the staircase region. The grooves may be filled with a first material, e.g., oxide. In other embodiments, the grooves may be filled with any other suitable dielectric material.

Once the grooves have been filled with the first material, a plurality of vertical channel holes may be etched within the stack. Memory layers and channel layers may, in some examples, be deposited onto walls of the vertical holes followed by deposition of a first material, e.g., oxide, to partially or fully fill the vertical channel holes to forming vertical NAND strings for the 3D-NAND memory device.

In other embodiments, after the channel holes are filled, the second material, e.g., the nitride, may be removed from the stack. For example, the nitride may be etched from the stack.

Once the nitride has been removed from the stack, a third material, e.g., a metal such as tungsten, may be deposited into the spaces reserved by nitride. The third material generally serves as transistor gates, wordlines, and selection signal lines for the 3D-NAND memory device and this approach of removing silicon nitride layers and replacing them with conductive material (e.g. tungsten) is commonly known as replacement gate technology. Before replacement by tungsten, one or more layers of materials may be deposited, for example, aluminum oxide, titanium nitride, etc. for performance and process benefits. The third material in conjunction with the memory layers and channel layers formed in channel holes form the stack or string of memory cells of the 3D-NAND memory device. In embodiments, one or more of the cells or layers at the top and at the bottom of the 3-D memory device may act differently from other cells or layers in the 3-D memory device (i.e. cells or layers in the middle of the 3-D memory device). For example, some cells or layers may be configured to act as string selection, source selection, or even dummy cells. The dielectric filled grooves divide the third material around channel holes into separate strips. Thus, the memory cells are effectively split with one side of a channel engaging the third material in one strip and the other side of the channel engaging another strip of the third material of the word plane, thereby increasing (doubling in this example) a density of the memory stack.

In another embodiment, a vertical NAND string may have one vertical hole (circular, elongated or any other regular or irregular shape) and several memory cells per hole on the same word plane may be formed. This may be done by creating a physical separation between one or more of the memory and channel layers deposited within the hole.

After the vertical NAND string formation, contacts may be formed on the vertical NAND strings and bitlines comprising, for example, copper lines, may be formed over the NAND strings and electrically coupled to the NAND strings through the contacts.

In some embodiments, the method further includes forming separation trenches in the stack. The separation trenches may extend in parallel with the grooves. The separation trenches may be utilized to remove the second material, e.g., the nitride, and to backfill the stack with the third material, e.g., the tungsten. In some embodiments, the separation trenches are wider than the grooves.

In some embodiments, the substrate may comprise silicon or polysilicon and diffusions in the substrate may serve as common source for the vertical NAND strings. In other embodiments, pipe connections may be formed in the substrate to electrically couple the lower ends of two adjacent vertical NAND strings.

In some embodiments, the grooves may be formed in a discontinuous manner with gaps between the segments of grooves in a length-wise direction. In such embodiments, after the grooves are filled with dielectric, e.g., the first material, separation trenches may be etched in the stack. During the replacement metal gate process, the gaps provide a path for removing the second material, e.g., nitride, and depositing the third material.

Examples of methods for depositing the third material into the stack include, for example, atomic layer deposition, chemical vapor deposition, physical vapor deposition, plasma-assisted atomic layer deposition, and/or plasma-enhanced chemical vapor deposition. Once the third material has been deposited into the stack, the materials left in the separation trenches may be removed, isolation trenches may be etched through the stack at the locations of the gaps, and the trenches may then be filled with the first material, e.g., oxide.

In some embodiments, instead of forming separation trenches in the stack, the second material may be removed from the stack through a plurality of holes etched through the stack, with at least one hole etched through each continuous dielectric filled groove without gaps. Once the second material has been removed, the third material may be deposited into the stack through the holes which may be smaller or larger in diameter as when compared to the channel holes.

### Example Embodiments

The memory cells in a NAND flash memory device are organized in matrix of NAND strings. Each of the NAND strings may include a source selection transistor coupled to a sourceline (SL), a string selection transistor coupled to a bitline (BL), and a plurality of memory cell transistors connected in series between and electrically coupled to the string and source selection transistors. 3D-NAND flash memory devices comprise vertically stacked memory cells organized in vertical NAND strings.

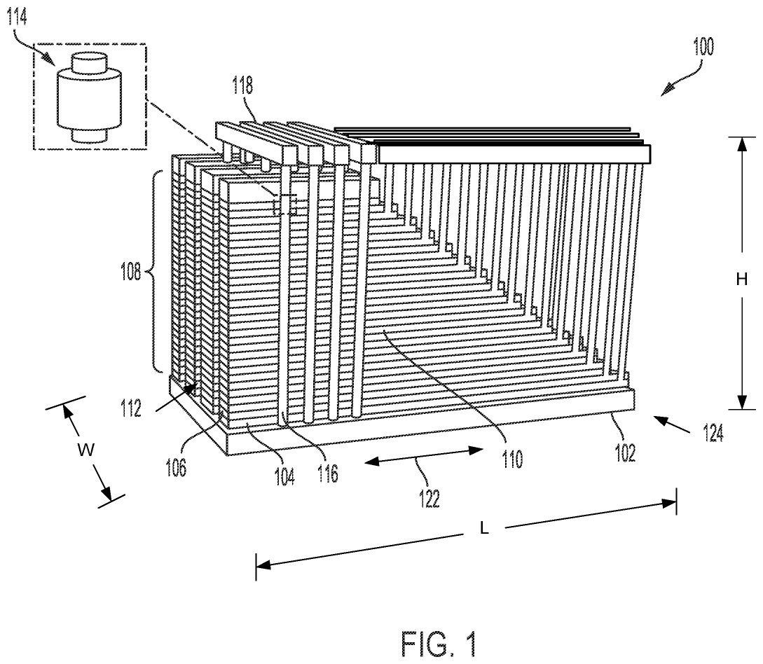

FIG. 1 is a perspective view of an example 3D-NAND memory device 100. The 3D-NAND memory device 100 includes a substrate 102. The substrate may comprise an insulating material, for example, silicon oxide, silicon nitride, and/or a semiconductor material such as, for example, silicon, polysilicon, etc. Alternating insulative layers 104, e.g., silicon oxide, and conductive material layers 106, e.g., polysilicon, doped polysilicon, silicon, or metal such as, for example, tungsten, as will be described further herein, are deposited on the substrate 102 to form stacks 108. The conductive material layers 106 may be referred to as gate planes herein since the conductive material layers 106 provide memory transistor gates, selection transistor gates, word lines, and selection signal lines for the 3D-NAND memory device 100. Separation or isolation trenches 112 may be provided between stacks 108. Spaces between two adjacent separation trenches 112 may vary in different NAND string architectures, as will be described further herein.

As can be seen in FIG. 1, individual memory cells 114 are vertically stacked in vertical NAND strings 116. Each individual memory cell 114 comprises a vertical channel and corresponding gate material in gate planes 106 around the channel in a gate-all-around architecture, or, as will be described further herein, split-cell architecture. Each memory cell 114 comprises a memory layer (not shown) that includes a charge storage layer, a blocking dielectric that separates the charge storage layer from the gate region, and a tunneling dielectric that separates the charge storage layer from the channel region. In one embodiment, the memory layer comprises a charge trapping layer (e.g. silicon nitride). In another embodiment, the memory layer comprises a floating gate.

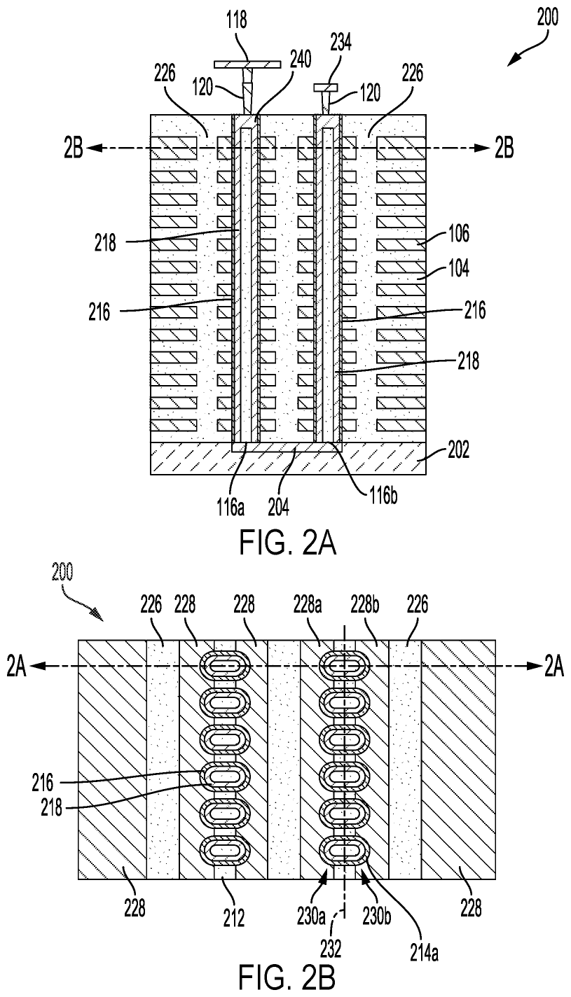

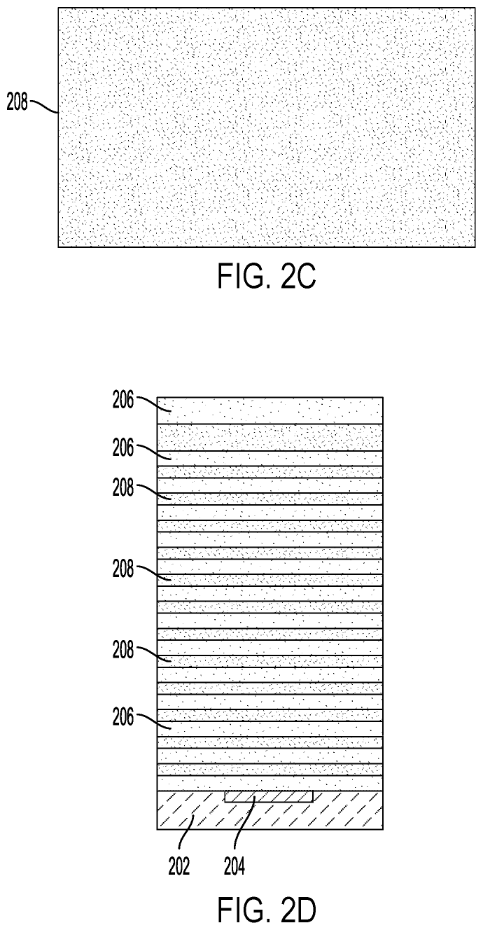

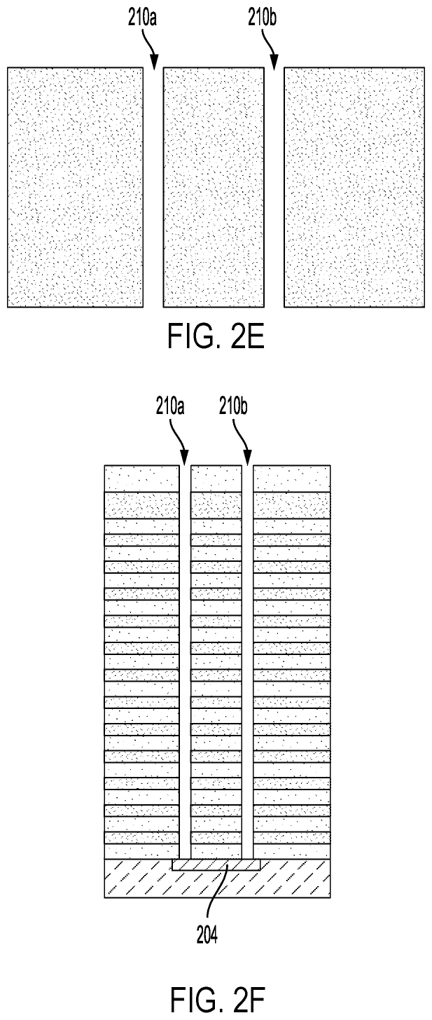

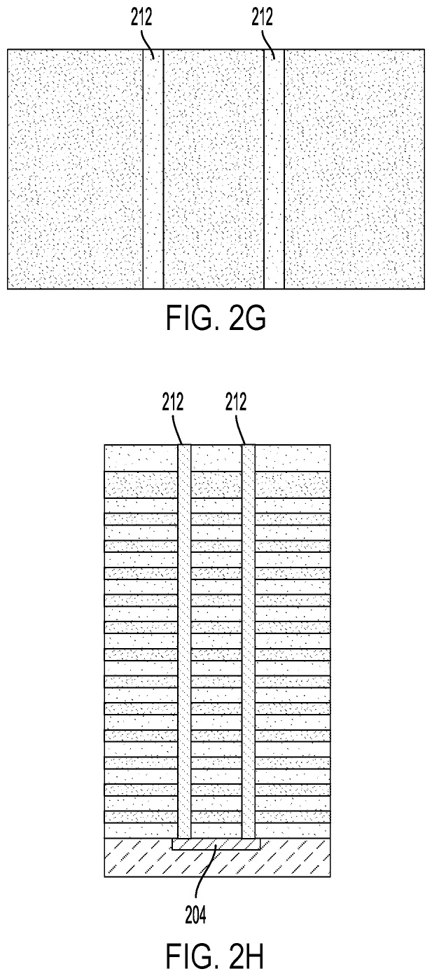

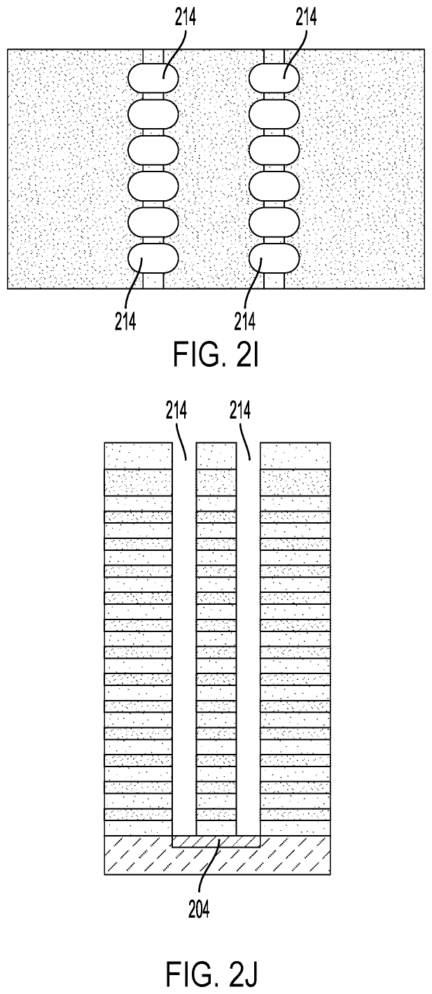

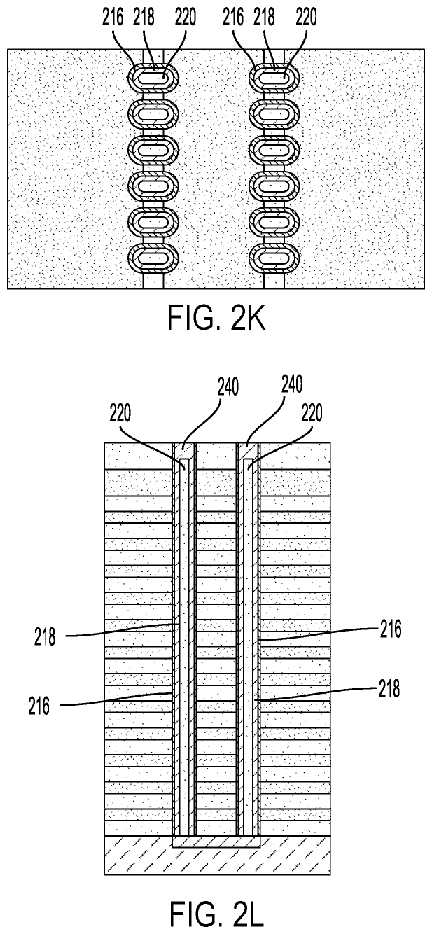

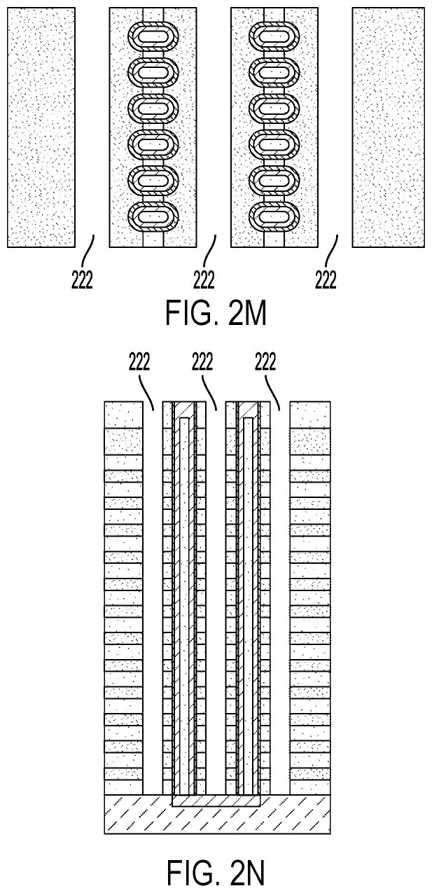

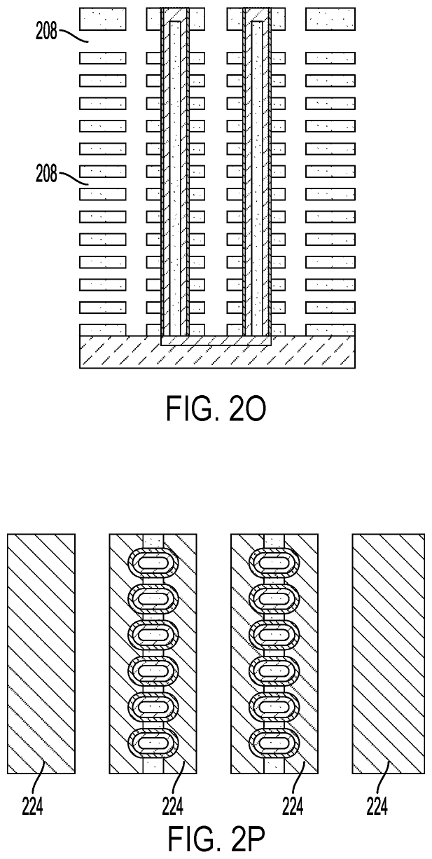

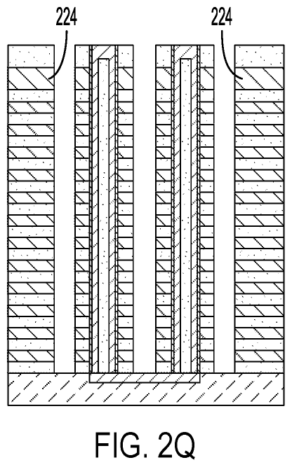

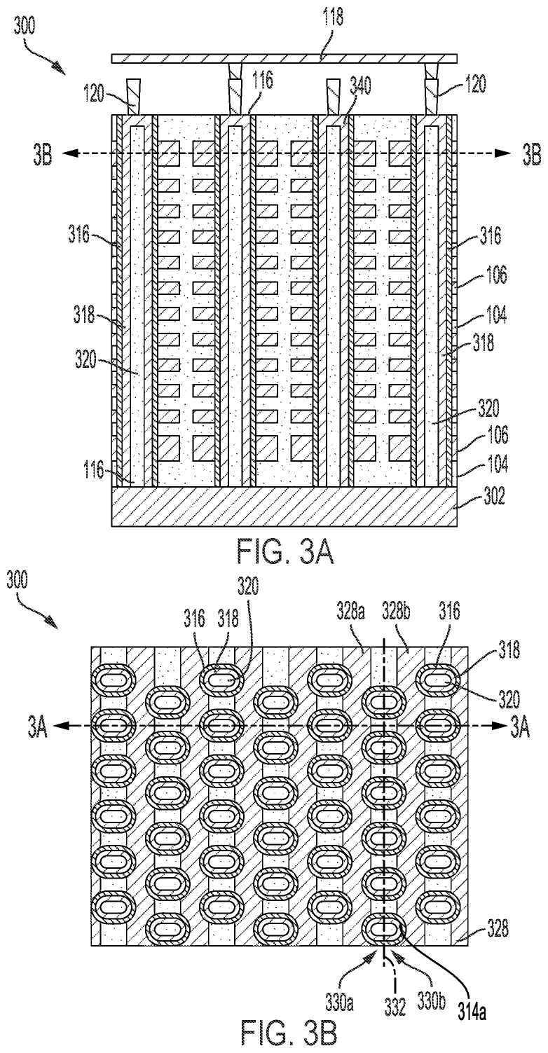

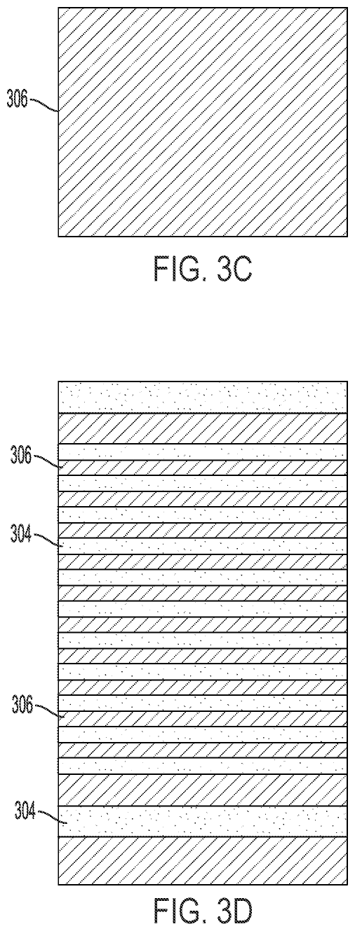

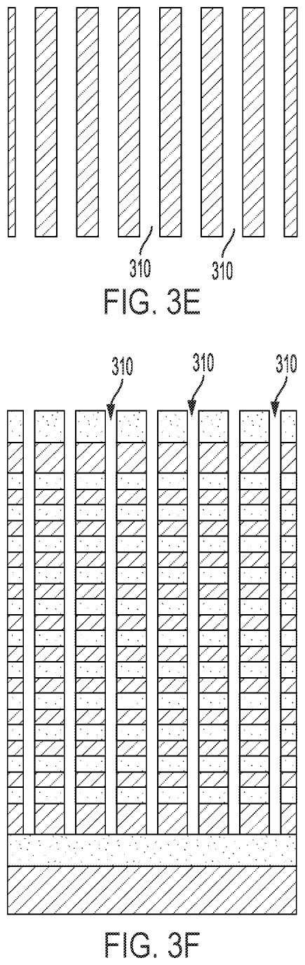

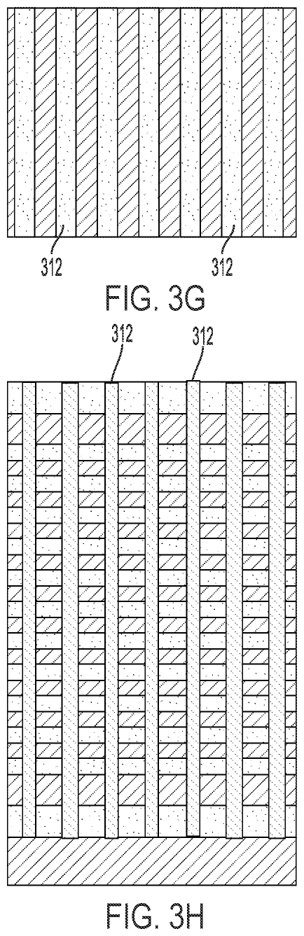

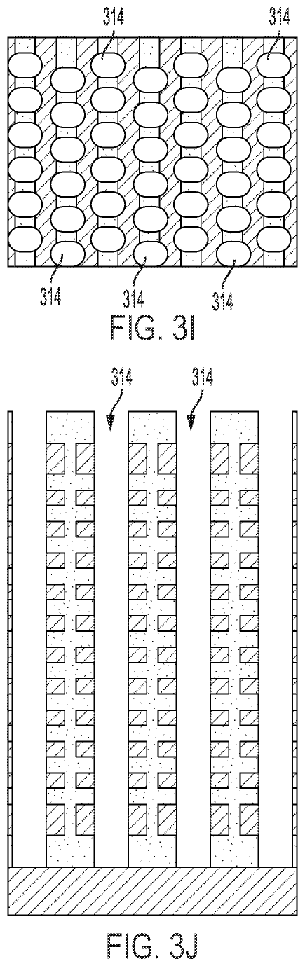

Bitlines 118, which may comprise a conductive material such as, for example, copper, are at the top of the vertical NAND strings 116 and coupled to the NAND strings through bitline contacts (not shown) that may comprise a conductive material, for example copper or tungsten. In one embodiment (as will be described with respect to FIGS. 2A-2Q), the NAND strings 116 have a U-shape, wherein lower ends of two adjacent vertical strings 116 are electrically connected through a pipe connection (not shown in FIG. 1), the upper end of one vertical string 116 is coupled to a bit line 118 through a bit line contact, the upper end of another vertical string 116 is coupled to a source line through a source line contact, and the uppermost transistors or group of transistors of the two vertical strings 116 are used as string and source selection transistors, respectively. In other embodiments (as will be described with respect to FIGS. 3A-3J, the NAND strings 116 have a straight shape, wherein the upper end of each vertical string 116 is coupled to a bit line 118 through a bit line contact with the uppermost transistor or group of transistors used as string selection transistor, and the lower end of each vertical string 116 is coupled to a source line through a source line contact with the lower most transistor or group of transistors used as source selection transistor.

As can be seen in FIG. 1, the stacks 108 are formed with a staircase shape 124 for making electrical contacts to gate planes 106. Arrow 122 illustrates the longitudinal direction of dielectric filled grooves (not illustrated in FIG. 1) and separation trenches 112 in the 3D-NAND memory device 100, as will be discussed further herein. The dielectric filled separation trenches 112 and dielectric filled grooves may extend along a length L of the 3D-NAND memory device 100.

FIGS. 2A-2Q schematically illustrate an example method of manufacturing one type of 3D-NAND memory device, e.g., 3D-NAND memory device 100 of FIG. 1. FIG. 2A is a cross-sectional view of a portion 200 of the 3D-NAND memory device as seen along the line 2A-2A of FIG. 2B. FIG. 2B is a planar view of the portion 200 of the 3D-NAND memory device as seen along the line 2B-2B of FIG. 2A. FIGS. 2C, 2E, 2G, 2I, 2K, 2M, and 2P are planar views of the portion 200 of the 3D-NAND memory device as seen along the line 2B-2B of FIG. 2A during various stages of the manufacturing process. FIGS. 2D, 2F, 2H, 2J, 2L, 2N, 2O, and 2Q are cross-sectional views of the portion 200 of the 3D-NAND memory device as seen along the line 2A-2A of FIG. 2B during various stages of the manufacturing process. The portion 200 may represent at least a portion of a stack 108 of the 3D-NAND memory device 100 of FIG. 1.

As may be seen in FIG. 2A, the portion 200 includes a substrate 202, e.g., substrate 102, that includes a pipe connection 204. In embodiments, substrate 202 may include one or more layers of conductive and/or non-conductive layers, of varying thicknesses. In embodiments, substrate 202 may also include an active layer that comprises NMOS and PMOS transistors.

As described with respect to FIG. 1, the portion 200 includes alternating layers 104 of insulating material, e.g., oxide, and layers 106 of conductive material, e.g., a metal such as tungsten. Other metals or conductive materials may be used if desired. The portion 200 also includes vertical strings 116a, 116b located over a pipe connection 204. Vertical strings 116a, 116b comprise vertically stacked transistors with portions of the conductive material layers 106 used as transistor gates and, as previously noted, the conductive material layers 106 may also be called gate planes. The gate planes 106 are around channel holes 214 formed through the alternating layers stack 108 of layers 104, 106. Channel layers 218 are formed on the sidewalls of channel holes 214. A memory layer 216 is formed between the gate planes 106 and channel layers 218. The memory layer 216 may comprise a charge storage layer separated from the gate planes by a blocking dielectric and separated from the channel layers by a tunneling dielectric (not shown). A portion of the gate plane 106 and the corresponding portions of the memory layer and channel layer form a memory cell transistor (e.g., memory cell 114 of FIG. 1 and as can be seen in FIG. 2B at 230a, 230b). A portion of the gate plane 106 and the corresponding portion of the channel layer with or without memory layer form a selection transistor. Vertically stacked memory cell transistors and selection transistors form the vertical strings 116a and 116b.

Pipe connection 204 electrically couples the lower ends of vertical strings 116a and 116b, forming a U-shaped NAND string. In one embodiment, the pipe connection 204 is an inverted region controlled by a gate plane 106 or a group of gate planes 106 around the lower end of vertical strings 116a and 116b. In another embodiments, the pipe connection 204 is a conductive material such as doped polysilicon or metal that is electrically isolated from the substrate 202. Contacts 120 are provided at the upper ends of the vertical strings 116a and 116b and couple the upper ends of 116a and 116b to bit line 118 and source line 234, respectively. A conductive material 240 embedded in the channel holes 214 at the upper ends of vertical strings 116a and 116b and electrically connected to the channel layers 218 provides landing pads for the bit line and source line contacts 120. The uppermost transistors or group of transistors of the vertical strings 116a and 116b are used as string and source selection transistors, respectively.

As illustrated in FIG. 2A and FIG. 2B, dielectric filled separation trenches 226 and grooves 212 separate the gate planes 106 into strips (for example, 228, 228a, 228b) providing transistor gates as well as word lines and string/source selection signal lines. The channel holes 214 are formed through the dielectric filled grooves 212. The channel layers 218 formed on the sidewalls of the channel holes 214 have two portions controlled by separate gates at each layer of gate planes 106. Accordingly, the circular memory cells 114 of the 3D-NAND memory device 100 of FIG. 1 are split into two, separate memory cells having a substantially semicircular or curved shape. For example, as illustrated in FIG. 2B, the memory cells on the left and right sides of line 232 are effectively split with one side 230a of the channel layer in channel hole 214a engaging the gate material in one strip 228a to form a first memory cell and the other side 230b of the channel layer in channel hole 214a engaging another strip 228b to form a second memory cell.

Referring to FIGS. 2C and 2D, for the example method of FIGS. 2A-2Q, alternately stacked layers 206 (corresponding to layers 104) of insulating material, e.g., silicon oxide, and layers 208 of sacrificial material are deposited on substrate 202. In embodiments, the sacrificial material may include silicon nitride, silicon oxynitride, silicon carbide, amorphous silicon, or poly-crystalline silicon that can be selectively removed in a later process to provide spaces for forming metal layers corresponding to gate planes 106 that form word lines and selection signal lines in portion 200. Layers 206 and 208 may have the same thickness or may, in embodiments, have thicknesses that are different.

Referring to FIGS. 2E and 2F, once the stack of layers 206, 208 has been formed, a plurality of grooves 210 may be defined within the portion 200. In the example of FIGS. 2A-2Q, two grooves 210a and 210b are illustrated, although more grooves 210 are generally included. As may be seen in FIG. 2F, in some embodiments, the grooves 210a and 210b are etched through all of the layers 206, 208 and partially expose the pipe connection 204. In other embodiments, some grooves 210 may be etched through all of the layers 206, 208 and other grooves 210 may be etched through a majority of the layers 206, 208 and leave some of the layers 206, 208 at the bottom of the stack unetched such that after the sacrificial layers 208 are replaced by gate planes in a later process, e.g., gate planes 106, some gate planes at the bottom of the stack may be used as control gates.

In embodiments, the grooves 210 extend in the same longitudinal direction as the dielectric filled separation trenches 226 as illustrated by arrow 122 in FIG. 1. In embodiments, the grooves 210 may also extend partially or entirely through the staircase region 124 of FIG. 1 in the longitudinal direction. In one embodiment, the grooves 210 may extend through the entire staircase region 124 in the longitudinal direction to isolate the word lines and selection signal lines on the opposite sides of the grooves 210. In another embodiment, the grooves 210 may extend partially through the staircase region 124 in the longitudinal direction such that the word lines on the opposite sides of the grooves 210 are isolated by the grooves 210 and the selection signal lines on the opposite sides of the grooves 210 remain connected.

Referring to FIGS. 2G and 2H, the grooves 210a, 210b may be filled with insulating dielectric material to form dielectric filled grooves 212. The insulating dielectric material may be the same material as layers 206.

Once the grooves 210a and 210b have been filled with insulating material to form dielectric filled grooves 212, referring to FIGS. 2I and 2J, channel holes 214 may be etched through the stack of layers 206, 208 and the dielectric filled grooves 212 to partially expose the pipe connection 204. In embodiments, the channel holes 214 may be wider than the width of the dielectric filled grooves 212 in a direction orthogonal to the longitudinal direction as illustrated in FIG. 1, and the channel holes have substantially semicircular or curved portions on the opposite sides of the dielectric filled grooves 212.

Referring to FIGS. 2K and 2L, memory layers 216 comprising one or more material layers may be deposited onto walls of the channel holes 214. In embodiments, the memory layers 216 comprise a charge storage layer, a first dielectric between the channel hole sidewall and the charge storage layer and a second dielectric over the charge storage layer. The first dielectric may include silicon oxide, silicon oxynitride, aluminum oxide, aluminum oxynitride, and a combination of such materials and may be used as blocking oxide or part of blocking oxide in a flash memory cell transistor. The second dielectric may be used as tunneling dielectric in a flash memory cell transistor. In one embodiment, the charge storage layer comprises a charge trapping layer (e.g. silicon nitride). In another embodiment, the charge storage layer comprises a floating gate. The floating gate may be formed by first selectively recessing the sacrificial layer 208 in the channel holes 214 and forming floating gates into the recesses with the floating gates isolated from layers 206 and 208 by the first dielectric or part of the first dielectric.

Once the memory layers 216 have been deposited within the channel holes 214, a channel material 218 may be formed over the memory layers 216 within the channel holes 214. In embodiments, the channel material 218 may be a conformal layer and may include amorphous, single-crystalline, or poly-crystalline semiconductor materials and may be formed using a CVD process, an ALD process, an epitaxial growing process, or a combination of these processes. In embodiments, a thermal treatment may be performed to transform the amorphous semiconductor materials to poly-crystalline or single-crystalline materials, to transform the poly-crystalline semiconductor materials to single-crystalline materials, or to change the grain sizes of the poly-crystalline semiconductor materials. In one embodiment, a thermal treatment may be performed to transform the poly-crystalline semiconductor materials to single-crystalline materials using a metal-induced-crystalline process. In one embodiment, the channel material 218 may include amorphous, single-crystalline, or poly-crystalline silicon or silicon germanium materials. In embodiments, the channel material 218 may be a conformal layer and have a thickness that partially fills the channel holes 214. An insulating material 220, e.g. silicon oxide, may fill the channel holes 214. In one embodiment, the insulating material 220 may be a conformal layer over the channel material 218 having a thickness that partially fills the channel holes 214 and leaves a void in the center of channel holes 214. Once the material layers 216, channel material 218, and insulating material 220 are formed in the channel holes 214, a recess may be formed at the upper ends of the channel holes 214 and conductive material landing pads 240 may be formed in the recess as bit line and source line contact landing pads. The conductive material for the landing pads 240 may include doped polysilicon or metals.

In embodiments, the channel material 218 and the material of the landing pads 240 may be different. For example, in embodiments, the channel material may comprise polysilicon and the landing pads 240 may comprise a polysilicon, a similar material, or a different material.

Referring to FIGS. 2M and 2N, trenches 222 are formed, e.g., etched, in the portion 200. In the example method of FIGS. 2A-2Q, trenches 222 are formed on both sides of dielectric filled grooves 212. In some embodiments, as may be seen in FIG. 2N, the trenches 222 are etched through all of the layers 206, 208 and partially expose the substrate 202. In other embodiments, some trenches 222 may be etched through all of the layers 206, 208 and other trenches 222 may be etched through a majority of the layers 206, 208 and leave some of the layers 206, 208 at the bottom of the stack unetched such that after the sacrificial layers 208 are replaced by gate planes in a later process, some gate planes at the bottom of the stack may be used as control gates.

In embodiments, the trenches 222 extend in the longitudinal direction as illustrated by arrow 122 in FIG. 1. In embodiments, like the dielectric filled grooves 212, the trenches 222 may also extend partially or entirely through the staircase region 124 of FIG. 1 in the longitudinal direction. In one embodiment, the trenches 222 may extend through the entire staircase region 124 in the longitudinal direction to isolate the word lines and selection signal lines on the opposite sides of the trenches 222. In another embodiment, the trenches 222 may extend partially through the staircase region 124 in the longitudinal direction such that the word lines on the opposite sides of the separation trenches 222 are isolated by the trenches 222 and the selection signal lines on the opposite sides of the trenches 222 remain connected.

Referring to FIG. 2O, the trenches 222 expose the sacrificial layers 208 from the trench sidewalls. The sacrificial layers 208 may be selectively removed to form gate regions via, for example, a wet etching process from the trenches 222. Referring to FIGS. 2P and 2Q, in embodiments, a conformal oxide layer (e.g., silicon oxide, silicon oxynitride, aluminum oxide, aluminum oxynitride, or a combination of such dielectrics) may be formed in the gate regions using an ALD process. A metal gate may be deposited to form metal layers (e.g. 224) corresponding to gate planes 106 that form word lines and selection signal lines in portion 200. In one embodiment, the metal layer comprises a conformal TiN layer deposited over the conformal oxide layer using an ALD process, and a tungsten layer that partially or completely fills the remaining gate regions deposited using an ALD or CVD process. Once the gate regions are filled, an anisotropic etching is performed to remove materials left in the trenches 222. Referring back to FIG. 2A, the trenches 222 may be filled with an insulating dielectric material to form the dielectric filled separation trenches 226. In one embodiment, the insulating dielectric material comprises the same material as layer 104 in FIG. 2A and the insulating material layer 206 in FIG. 2D (e.g., silicon oxide).

Referring back to FIGS. 2A and 2B, the dielectric filled separation trenches 226 separate gate planes 106 into strips (e.g., 228, 228a, 228b) that form word lines and selection signal lines in portion 200. The gate planes 106 in conjunction with the corresponding portions of memory layers and channel layers formed on the sidewalls of channel holes form the memory cells 114 of the 3D-NAND memory device 100 as illustrated in FIG. 1. The dielectric filled grooves 212 effectively split a gate-all-around cell into two separate cells having substantially semicircular or curved channels at each level of the gate planes 106 around the channel holes 214. This is achieved by splitting the gates of the two transistors.

FIGS. 3A-3J schematically illustrate another example method of manufacturing another type or structure of a 3D-NAND memory device, e.g., 3D-NAND memory device 100 of FIG. 1. FIG. 3A is a cross-sectional view of a portion 300 of the 3D-NAND memory device as seen along the line 3A-3A of FIG. 3B. FIG. 3B is a planar view of the portion 300 of the 3D-NAND memory device as seen along the line 3B-3B of FIG. 3A. FIGS. 3C, 3E, 3G, and 3I, are cross-sectional views of the portion 300 of the 3D-NAND memory device as seen along the line 3A-3A of FIG. 3B during various stages of the manufacturing process. FIGS. 3D, 3F, 3H, and 3J are planar views of the portion 300 of the 3D-NAND memory device as seen along the line 3B-3B of FIG. 3A during various stages of the manufacturing process. The portion 300 may represent at least a portion of a stack 108 of the 3D-NAND memory device 100 of FIG. 1.

As may be seen in FIG. 3A, the portion 300 includes a substrate 302, e.g., substrate 102. The substrate 302 may include one or more layers of conductive and/or non-conductive layers, of varying thicknesses. The substrate 302 may also include an active layer that comprises NMOS and PMOS transistors. As described with respect to FIG. 1, the portion 300 includes alternating layers 104 of insulating material, e.g., oxide, and layers 106 of conductive material. In the example method of FIGS. 3A-3J, the conductive material comprises silicon or polysilicon. The portion 300 also includes vertical NAND strings 116. As previously noted, vertical NAND strings 116 comprise vertically stacked transistors with portions of the conductive material layers 106 used as transistor gates and, as previously noted, the conductive material layers 106 may also be called gate planes. The gate planes 106 are around channel holes 314 formed through the alternating layers 104, 106. Memory layers 316 and channel layers 318 are formed on the sidewalls of channel holes 314. In embodiments, memory layer 316 comprises a charge storage layer, a blocking dielectric that separates the charge storage layer from gate planes, and a tunneling dielectric that separates the charge storage layer from the channel layers. A portion of the gate plane 106 and the corresponding portions of the memory layer and channel layer form a memory cell transistor (e.g., memory cell 114 of FIG. 1 and as can be seen in FIG. 3B at 330a, 330b). A portion of the gate plane 106 and the corresponding portion of the channel layer with or without memory layer form a selection transistor. Vertically stacked memory cell transistors and selection transistors form the vertical strings 116.

Contacts 120 are provided at the upper ends of the vertical NAND strings 116. Bit lines 118 are connected to the contacts 120. A conductive material 340 embedded in the channel holes 314 at the upper ends of vertical strings 116 and electrically connected to the channel layers 318 provides landing pads for the bit line contacts 120. The uppermost transistors or group of transistors of the vertical strings 116 are used as string selection transistors. The lower end of each vertical string 116 is coupled to a source line through a source line contact with the lower most transistor or group of transistors used as source selection transistors.

Referring to FIGS. 3C and 3D, for the example method of FIGS. 3A-3J, alternating layers 304 (corresponding to layers 104) of oxide are deposited or stacked alternatingly with layers 306 (corresponding to layers 106) of silicon or polysilicon on the substrate 302. Although not shown in FIG. 3D, one or more conductive and nonconductive layers may be formed as the substrate 302, before depositing the alternating layers of 304 and 306.

Referring to FIGS. 3E and 3F, once the stack of layers 304, 306 has been formed, a plurality of grooves 310 may be etched within the portion 300. In the example of FIGS. 3A-3J, seven grooves 310 are illustrated, although more or fewer grooves 310 may be included. The grooves 310 may extend in the longitudinal direction as illustrated by arrow 122 in FIG. 1. In embodiments, the grooves 310 may be etched through all of the layers 304, 306 and extend through the entire staircase region 124 in the longitudinal direction to isolate the word lines and selection signal lines on the opposite sides of the grooves 310. In other embodiments, some grooves 310 may be etched through a majority of the layers 304, 306 and leave some of the layers 304, 306 at the bottom of the stack unetched. Likewise, some grooves 310 may extend partially through the staircase region 124 in the longitudinal direction such that portions of layers 306 on the opposite sides of the grooves 310 remain connected in the staircase region. Although only one groove 310 is shown in the longitudinal (long) direction, there may be more than one groove 310 in the longitudinal direction, e.g., two or more grooves 310.

In embodiments, the grooves 310 extend through all of the layers 304, 306 and extend a length equal to a length of the layers 304, 308. Thus, due to the staircase shape of the 3D-NAND memory device, as noted with respect to FIG. 1, the vertical depth and horizontal length of each groove 310 may vary. However, the grooves 310 in the staircase region 124 of the 3D-memory device 100 of FIG. 1 are not active (or may include dummy holes). In embodiments, as previously noted, arrow 122 in FIG. 1 illustrates the longitudinal direction of the grooves 310 in the 3D-NAND memory device 100.

Referring to FIGS. 3G and 3H, the grooves 310 may be filled with insulating material, e.g., silicon oxide, to form dielectric filled grooves 312. In some other embodiments, the grooves 310 do not extend through all of the layers 304, 306.

Once the grooves 310 have been filled, referring to FIGS. 3I and 3J, channel holes 314 may be etched through the stack to partially expose the substrate 302. As may be seen in FIG. 3J, the channel holes 314 are staggered, thereby providing a higher density of memory cells when the 3D-NAND memory device is complete. In other embodiment, the channel holes 314 may not be staggered.

Referring to FIGS. 3A and 3B, memory layers 316 and channel layers 318 may be deposited onto walls of the channel holes 314. In embodiments, the channel layers 318 may be a conformal layer and may include amorphous, single-crystalline, or poly-crystalline semiconductor materials and may be formed using a CVD process, an ALD process, an epitaxial growing process, or a combination of these processes. In embodiments, a thermal treatment may be performed to transform the amorphous semiconductor materials to poly-crystalline or single-crystalline materials, to transform the poly-crystalline semiconductor materials to single-crystalline materials, or to change the grain sizes of the poly-crystalline semiconductor materials. In one embodiment, a thermal treatment may be performed to transform the poly-crystalline semiconductor materials to single-crystalline materials using a metal-induced-crystalline process. In one embodiment, the channel material 318 may include amorphous, single-crystalline, or poly-crystalline silicon or silicon germanium materials. In embodiments, the channel layer 318 may be a conformal layer and have a thickness that partially fills the channel holes 314. Insulating material 320, e.g., oxide, may then be deposited into the channel holes 314 to fully or partially fill the channel holes 314 to form NAND strings 116 of the 3D-NAND memory device 100 of FIG. 1. Bit lines 118 comprising, for example, copper, may be formed over the NAND strings 116 and electrically coupled to NAND strings through bit line contacts 120. In embodiments, separation trenches (not illustrated) may be formed between other portions 300, e.g., stacks 108, of the 3D-NAND memory device and the separation trenches may extend in the longitudinal direction as illustrated by arrow 122 in FIG. 1.

In the embodiment of FIGS. 3A-3J, the conductive material layers 306, e.g., silicon or polysilicon, in conjunction with the memory layers 316 and channel layers 318 formed in the channel holes 314 form the memory cells 114 of the 3D-NAND memory device 100 as illustrated in FIG. 1. Referring to FIG. 3B, because the dielectric filled grooves 312 divide the conductive material layers 306 into separate strips 328, 328a, 328b, the memory cells 114 are effectively split into two separate portions on the opposite sides of the dielectric filled grooves 312. For example, the memory cells around channel hole 314a are effectively split with one side 330a of channel hole 314a engaging the material in one strip 328a to form a first memory cell and the other side 330b of the channel hole 314a engaging another strip 328b to form a second memory cell. Accordingly, the circular memory cells 114 of the 3D-NAND memory device 100 of FIG. 1 are split into two, separate memory cells having substantially semicircular or curved channels along line 332.

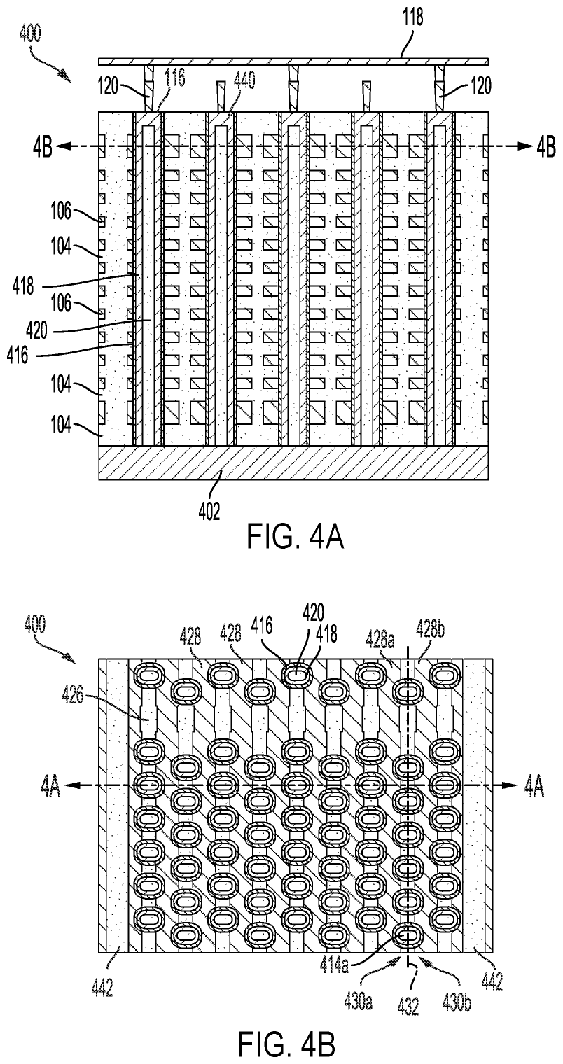

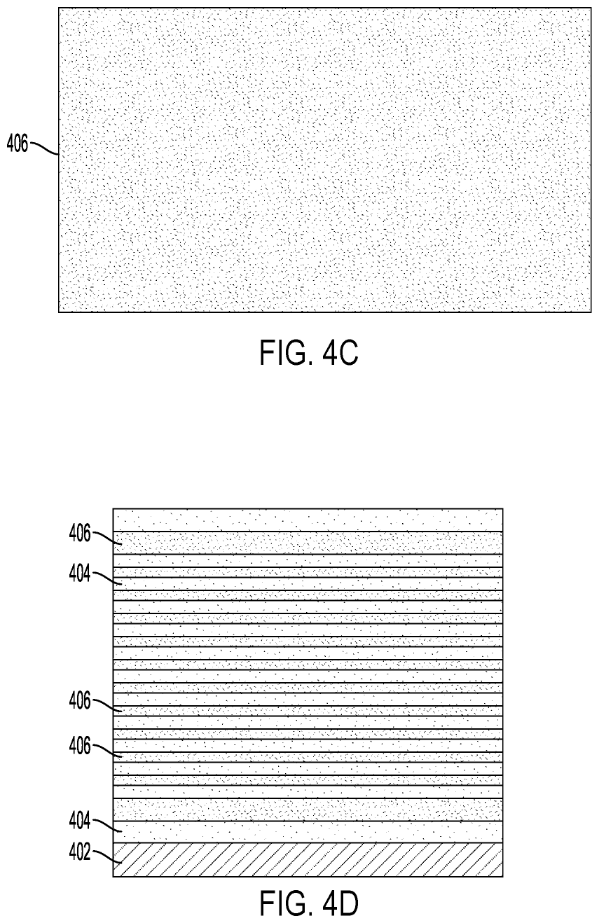

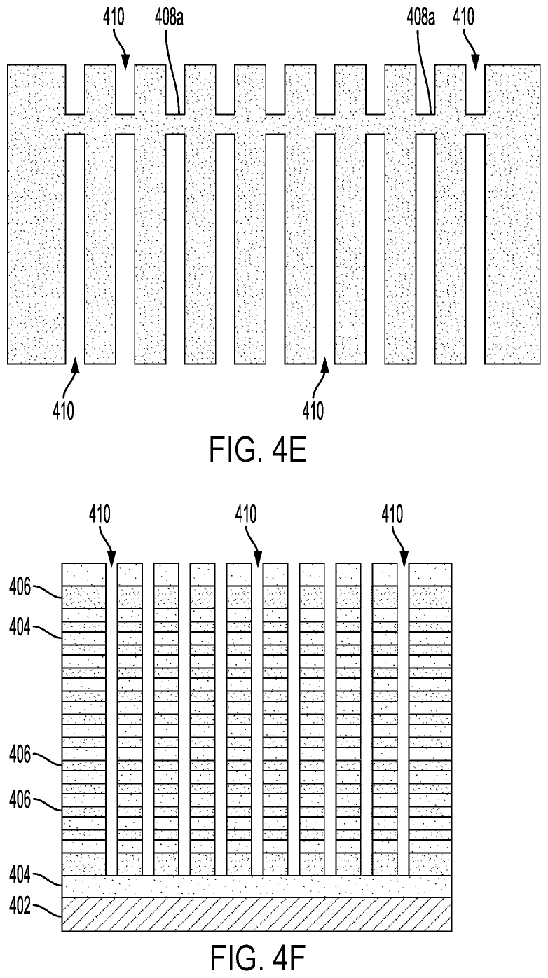

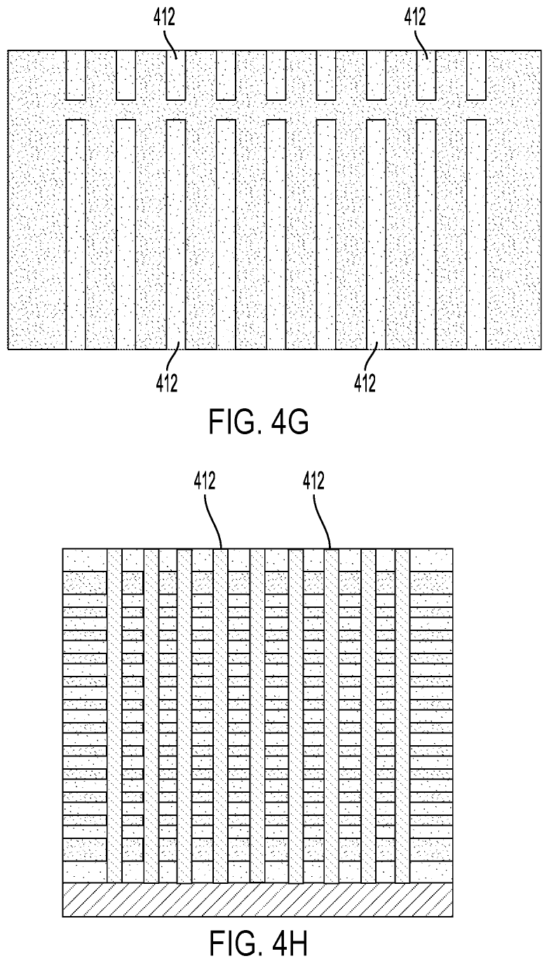

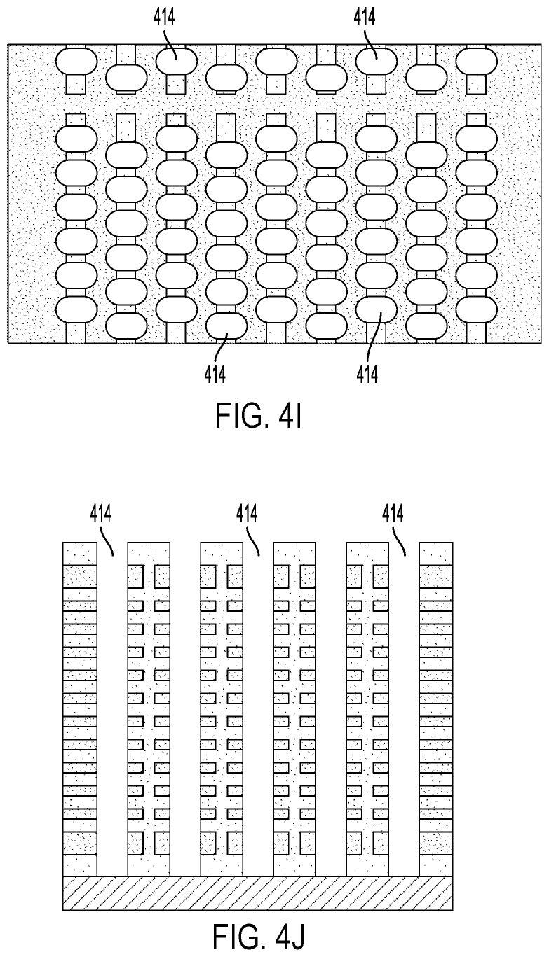

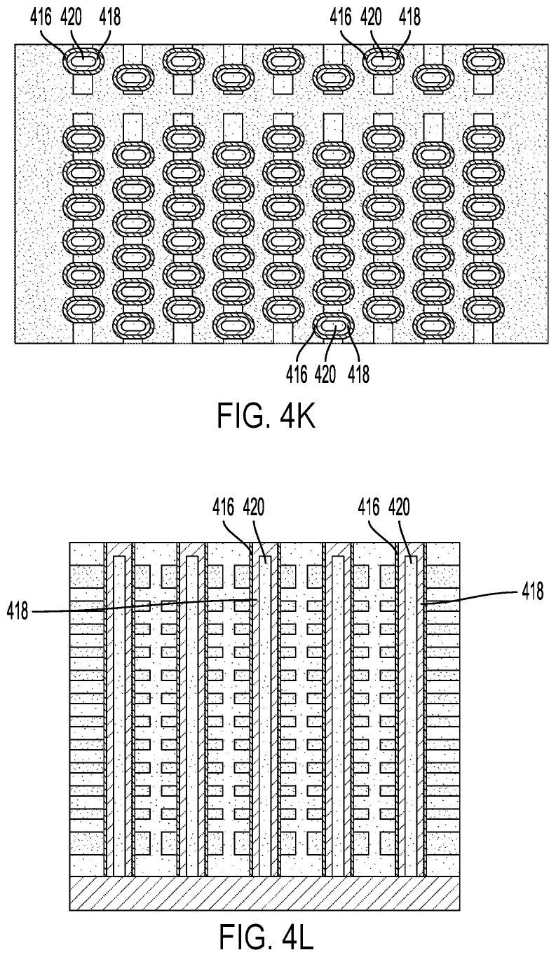

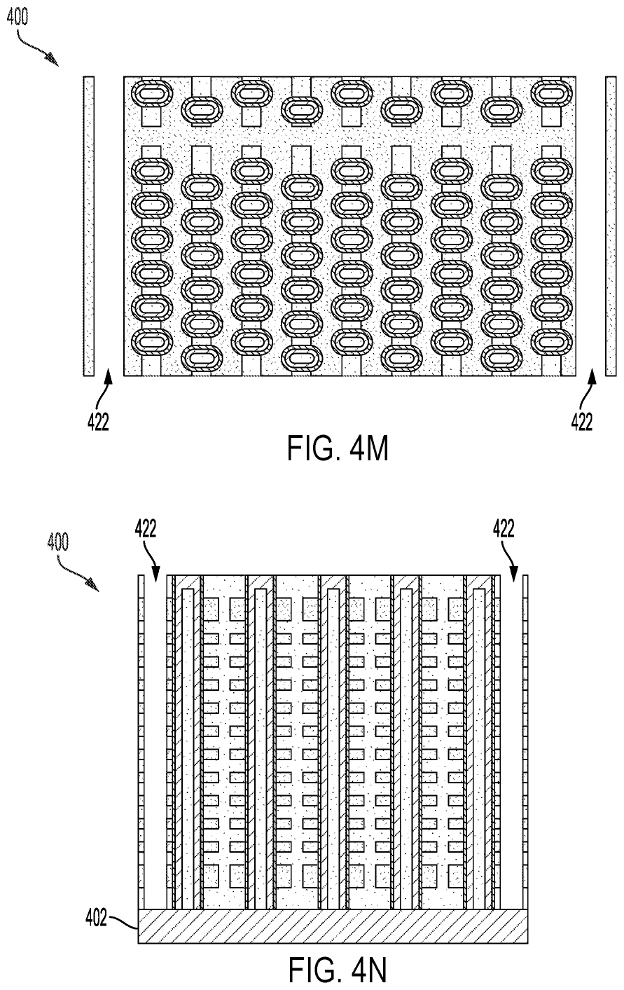

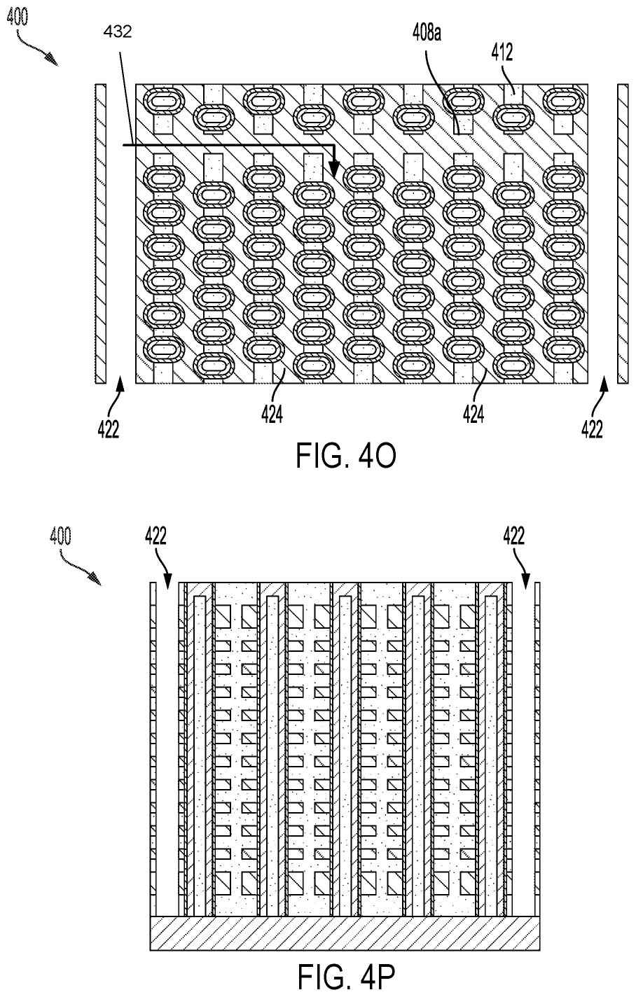

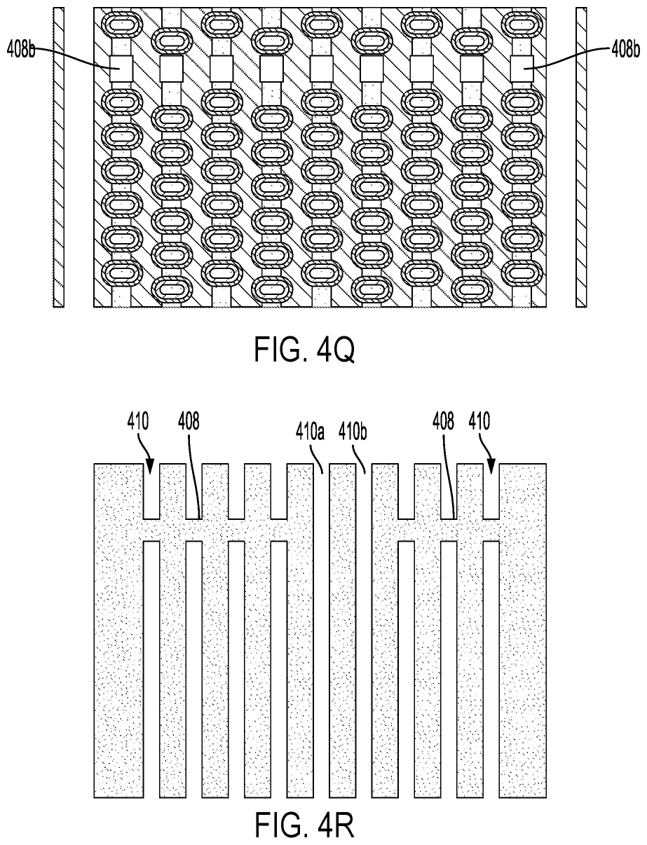

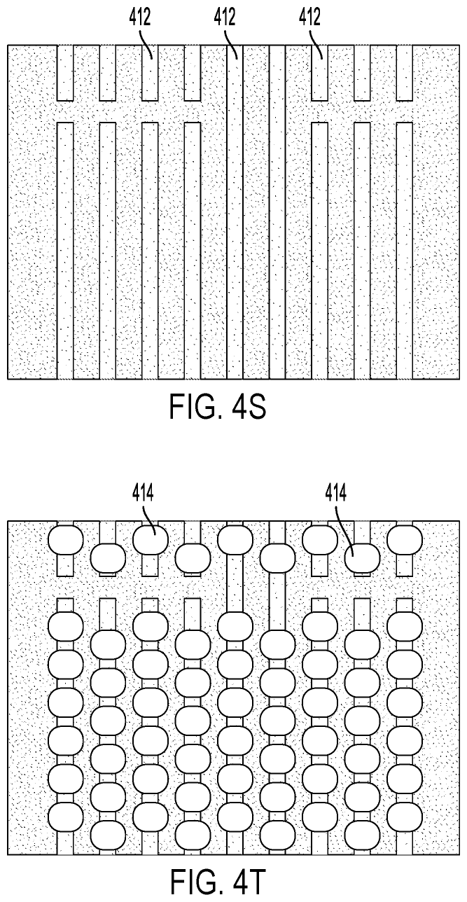

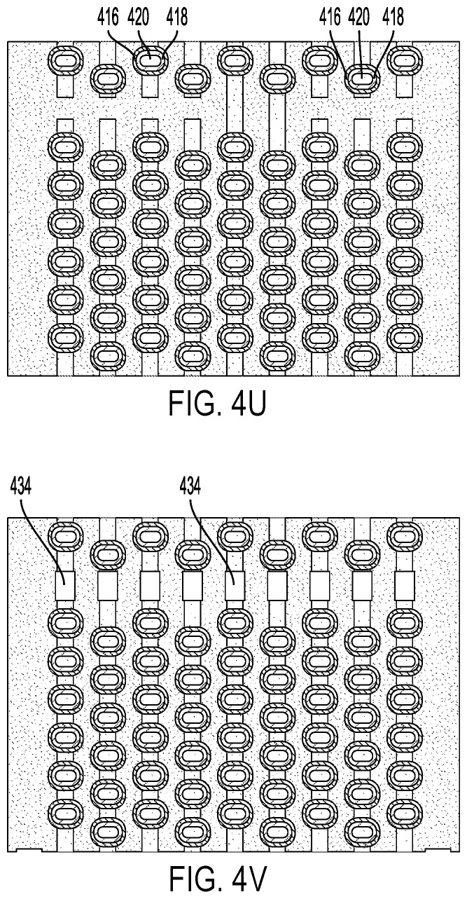

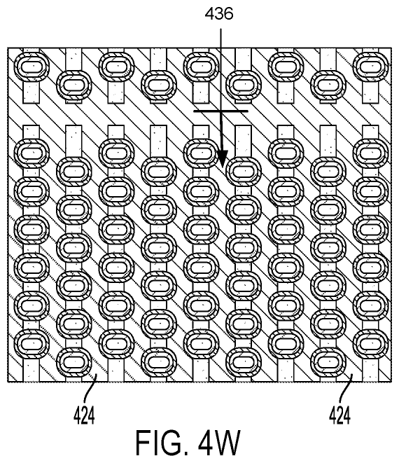

FIGS. 4A-4Q schematically illustrate another example method of manufacturing a 3D-NAND memory device, e.g., 3D-NAND memory device 100 of FIG. 1. FIG. 4A is a cross-sectional view of a portion 400 of the 3D-NAND memory device as seen along the line 4A-4A of FIG. 4B. FIG. 4B is a planar view of the portion 400 of the 3D-NAND memory device as seen along the line 4B-4B of FIG. 4A. FIGS. 4C, 4E, 4G, 4I, 4K, 4M, and 4P are planar views of the portion 400 of the 3D-NAND memory device as seen along the line 4B-4B of FIG. 4A during various stages of the manufacturing process. FIGS. 4D, 4F, 4H, 4J, 4L, 4N, 4O, and 4Q are cross-sectional views of the portion 400 of the 3D-NAND memory device as seen along the line 4A-4A of FIG. 4B during various stages of the manufacturing process. The portion 400 may represent at least a portion of a stack 108 of the 3D-NAND memory device 100 of FIG. 1.

As may be seen in FIG. 4A, the portion 400 includes a substrate 402, e.g., substrate 102. The substrate 402 may include one or more layers of conductive and/or non-conductive layers, of varying thicknesses. The substrate 402 may also include an active layer that comprises NMOS and PMOS transistors. The portion 400 also includes vertical NAND strings 116.

As previously noted, vertical NAND strings 116 comprise vertically stacked transistors with portions of the conductive material layers 106 used as transistor gates and, as previously noted, the conductive material layers 106 may also be called gate planes. The gate planes 106 are around channel holes 414 formed through the alternating layers 104, 106. Memory layers 416 and channel layers 418 are formed on the sidewalls of channel holes 414. In embodiments, memory layer 416 comprises a charge storage layer, a blocking dielectric that separates the charge storage layer from gate planes, and a tunneling dielectric that separates the charge storage layer from the channel layers. A portion of the gate plane 106 and the corresponding portions of the memory layer and channel layer form a memory cell transistor (e.g., memory cell 114 of FIG. 1 and as can be seen in FIG. 4B at 430a, 430b). A portion of the gate plane 106 and the corresponding portion of the channel layer with or without memory layer form a selection transistor. Vertically stacked memory cell transistors and selection transistors form the vertical strings 116.

As previously noted, contacts 120 are provided at ends of the vertical NAND strings 116. Bitlines 118 are connected to vertical strings 116 through the contacts 120. A conductive material 440 embedded in the channel holes 414 at the upper ends of vertical strings 116 and electrically connected to the channel layers 318 provides landing pads for the bitline contacts 120. The uppermost transistors or group of transistors of the vertical strings 116 may be used as string selection transistors. The lower end of each vertical string 116 is coupled to a source line through a source line contact with the lower most transistor or group of transistors used as source selection transistors.

Referring to FIGS. 4C and 4D, for the example method of FIGS. 4A-4Q, the alternating layers 404 (corresponding to layers 104) of oxide are deposited or stacked alternatingly with layers 406 (corresponding to layers 106) of sacrificial materials, e.g., nitride, on the substrate 402. In embodiments, the sacrificial materials may include silicon nitride, silicon oxynitride, silicon carbide, amorphous silicon, or poly-crystalline silicon that can be selectively removed in a later process to provide spaces for forming metal layers corresponding to gate planes 106 that form word lines and selection signal lines in portion 200. Referring to FIGS. 4E and 4F, once the stack of layers 404, 406 has been formed, a plurality of grooves 410 may be etched within the portion 400. In the example of FIGS. 4A-4Q, nine grooves 410 are illustrated, although more or fewer grooves 410 may be included. As may be seen in FIG. 4E, the grooves 410 are discontinuous, e.g., the grooves 410 include gaps 408a. In embodiments described with respect to FIGS. 2A-2Q and 3A-3J, the grooves 210, 310 may also be discontinuous. In embodiments, the grooves 410 may be etched through all of the layers 404, 406 and extend in the longitudinal direction as illustrated by arrow 122 in FIG. 1 when the gaps 408a are included. The grooves 410 may extend partially or entirely through the staircase region 124 as illustrated in FIG. 1 in the longitudinal direction. In other embodiments, some grooves 410 may be etched through a majority of the layers 404, 406 and leave some of the layers 404, 406 at the bottom of the stack unetched. Referring to FIGS. 4G and 4H, the grooves 410 may be filled with insulating material, e.g., oxide, to form dielectric filled grooves 412.

Once the grooves 410 have been filled, referring to FIGS. 4I and 4J, channel holes 414 may be etched through the stack to partially expose the substrate 402. As may be seen in FIG. 4I, the channel holes 414 are staggered to provide a higher density NAND string arrangement.

Referring to FIGS. 4K and 4L, memory layers 416 and channel layers 418 may be deposited onto walls of the channel holes 414 of FIGS. 4I and 4J. As previously noted, the channel layers 418 may be a conformal layer and may include amorphous, single-crystalline, or poly-crystalline semiconductor materials and may be formed using a CVD process, an ALD process, an epitaxial growing process, or a combination of these processes. In embodiments, a thermal treatment may be performed to transform the amorphous semiconductor materials to poly-crystalline or single-crystalline materials, to transform the poly-crystalline semiconductor materials to single-crystalline materials, or to change the grain sizes of the poly-crystalline semiconductor materials. In one embodiment, a thermal treatment may be performed to transform the poly-crystalline semiconductor materials to single-crystalline materials using a metal-induced-crystalline process. In one embodiment, the channel material 418 may include amorphous, single-crystalline, or poly-crystalline silicon or silicon germanium materials. In embodiments, the channel layer 418 may be a conformal layer and have a thickness that partially fills the channel holes 414 of FIGS. 4I and 4J. Insulating material 420, e.g., oxide, may then be deposited into the channel holes 414 of FIGS. 4I and 4J to fully or partially fill the channel holes 414 of FIGS. 4I and 4J to form NAND strings 116 of the 3D-NAND memory device 100 of FIG. 1.

Referring to FIGS. 4M and 4N, trenches 422 are formed, e.g., etched, in the portion 400 and partially expose the substrate 402. The trenches 422 may extend in the longitudinal direction as illustrated by arrow 122 in FIG. 1 and in parallel with the dielectric filled grooves 412 of FIGS. 4G and 4H. Referring to FIG. 4N, the trenches 422 expose the sacrificial layers 406 of FIG. 4F from the trench sidewalls. The sacrificial layers 406 of FIG. 4F may be selectively removed to form gate regions via, for example, a wet etching process from the trenches 422.

Referring to FIGS. 4O and 4P, once the sacrificial nitride has been removed from the portion 400, replacement metal 424, e.g., tungsten, corresponding to gate planes 106 may be formed into the gate regions through the trenches 422. Before replacement of the sacrificial nitride with the replacement metal 424, one or more layers of materials may be deposited, for example, aluminum oxide, titanium nitride, etc., for performance and process benefits. The replacement metal 424 may be deposited into gate regions, via, for example, atomic layer deposition, physical vapor deposition, chemical vapor deposition, plasma-assisted atomic layer deposition, and plasma-enhanced chemical vapor deposition from the trenches 422 and through the gaps 408a. Arrow 432 indicates an example path of removing sacrificial nitride and depositing metal 424. After filling the grooves 410 of FIGS. 4E and 4F with insulating material to form dielectric filled grooves 412 of FIGS. 4G and 4H, the gaps 408a are the only path in the vertical stacks for removing sacrificial nitride and depositing replacement metal, e.g., without the gaps 408a, the replacement metal 424 could not be deposited into the spaces between adjacent dielectric filled grooves 412.

Once the gate regions are filled, referring to FIG. 4Q, an anisotropic etching, is performed to remove materials left in the trenches 422. In addition, trenches 408b are etched through the stack at locations of the gaps 408a to isolate adjacent strips of replacement metal 424 (corresponding to the strips of gate planes 106) which serves as transistor gates, word lines, and selection signal lines for the 3D-NAND memory device 100. Referring back to FIG. 4B, the trenches 422 and 408b as illustrated in FIG. 4Q may be filled with insulating material to form dielectric filled separation trenches 442 and dielectric filled isolation trenches 426. The insulating material may comprise the same dielectric material as layer 404 in FIG. 4D or layer 104 in FIG. 4A (e.g., silicon oxide).

The replacement metal 424 in conjunction with memory layers 416 and channel layers 418 formed in the channel holes 414 form the memory cells 114 of the 3D-NAND memory device 100 as illustrated in FIG. 1. Referring to FIG. 4B, because the dielectric filled grooves 412 divide the replacement metal layers 424 into separate strips 428, 428a, 428b of the gate planes 106, the memory cells 114 are effectively split into two separate portions on the opposite sides of the dielectric filled grooves 412. For example, the memory cells around channel hole 414a are effectively split with one side 430a of channel hole 414a engaging the metal 424 in one strip 428a to form a first memory cell and the other side 430b of the channel hole 414a engaging another strip 428b to form a second memory cell. Accordingly, the circular memory cells 114 of the 3D-NAND memory device 100 of FIG. 1 are split into two, separate memory cells having substantially semicircular or curved channels along line 432.

Referring to FIGS. 4R-4W, an example alternative method may be described. As may be seen in FIG. 4R, two grooves 410a, 410b do not include gaps 408, e.g., grooves 410a, 410b are continuous. Generally, in this example, every other groove 410 is continuous.

Referring to FIG. 4S, the grooves 410 are filled with insulating material to form dielectric filled grooves 412, as previously described. Referring to FIGS. 4T and 4U, the channel holes 414 and vertical channels are formed as previously described in a staggered fashion to increase memory cell density. Referring to FIGS. 4V and 4W, trenches 434 are etched through the continuous dielectric filled grooves. The sacrificial nitride is then removed and metal 424 may be deposited through trenches 434. The metal 424 may be deposited into the conductive layers 406, via, for example, atomic layer deposition, chemical vapor deposition, plasma-assisted atomic layer deposition, and plasma-enhanced chemical vapor deposition from the trenches 422 through the vias 434. Arrow 436 indicates an example path of removing sacrificial nitride and depositing metal. Dielectric filled separation trenches 442 as illustrated in FIGS. 4A and 4B may be formed if desired to provide isolation between other portions 400, e.g., stacks 108, of the 3D-NAND memory device.

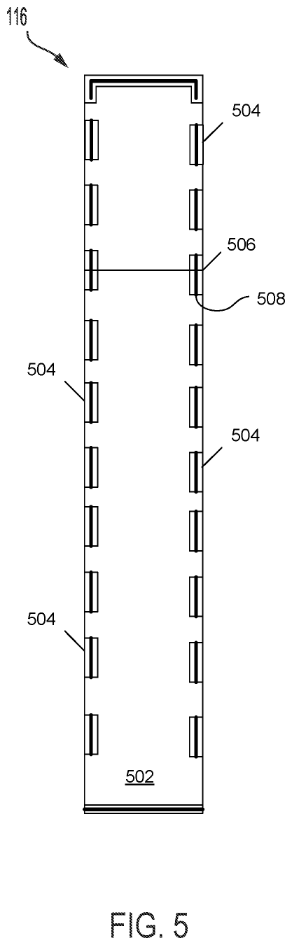

Referring to FIG. 5, in another embodiment, a single vertical NAND string 116 may have only one channel hole 502, e.g., hole 214, 314, 414, (circular, elongated or any other regular or irregular shape) within the vertical NAND string 116 that includes several memory cells 504, e.g., memory cells 114, per hole on the same gate plane 506, e.g., gate plane 106, may be formed. This may be done by creating a physical separation between one or more of materials layers 508, e.g., materials of the memory layers 216, 316, 416, deposited within the hole. For example, using techniques similar to those described herein, channels may be formed and then memory cells may be formed. The memory cells may be filled with oxide and then the oxide may be etched. The cell structures may then be etched to create multiple memory cells 504 within the channel hole 502.

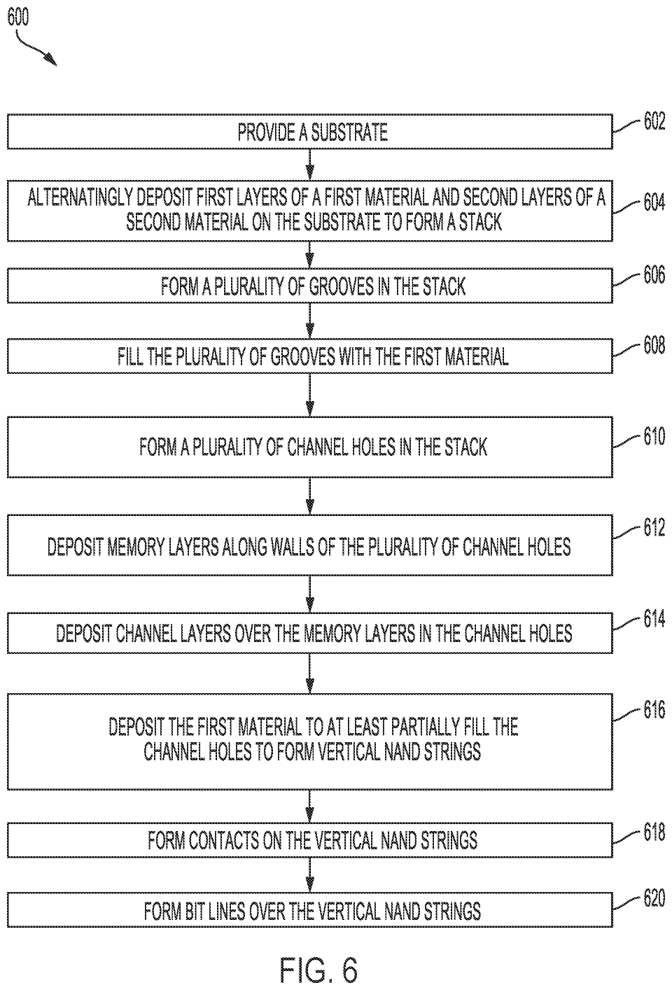

FIG. 6 illustrates a flow diagram of an example method 600 for manufacturing a 3D-NAND memory device, e.g., 3D-NAND memory device 100. In the flow diagram, the operations of method 600 are shown as individual blocks.

At block 602, a substrate is provided. For example, the substrate may be similar to substrate 102.

At block 604, first layers of a first material and second layers of a second material are alternatingly deposited on the substrate to form a stack. For example, the first layers may correspond to layers 104, 206, 304, or 404 and the first material may be oxide, while the second layers may correspond to layers 106, 224, 306, or 424 and the second material may be silicon, polysilicon, or a metal such as, for example, tungsten.

At block 606, a plurality of grooves is formed in the stack. For example, the grooves may correspond to grooves 210, 310, or 410.

At block 608, the plurality of grooves is filled with the first material, e.g., oxide. At block 610, a plurality of channel holes is formed through the stack, e.g., the alternating first and second layers. For example, the channel holes may correspond to channel holes 214, 314, or 414.

At block 612, memory layers are deposited along walls of the plurality of channel holes. For example, the memory layers may comprise a charge storage layer, a blocking dielectric, and a tunneling dielectric.

At block 614, channel layers are deposited over the memory layers in the channel holes. For example, silicon or polysilicon may be deposited over the memory layers in the channel holes. At block 616, the first material is deposited to at least partially fill the channel holes to form vertical NAND strings. For example, oxide may be deposited to partially or completely fill the channel holes thereby forming the vertical NAND strings.

At block 618, contacts, e.g., contacts 120, are formed on the vertical NAND strings. At block 620, bit lines, e.g., bit lines 118, are formed over the vertical NAND strings.

While the invention is described with respect to the specific examples, it is to be understood that the scope of the invention is not limited to these specific examples. Since other modifications and changes varied to fit particular operating requirements and environments will be apparent to those skilled in the art, the invention is not considered limited to the example chosen for purposes of disclosure and covers all changes and modifications which do not constitute departures from the true spirit and scope of this invention.

Although the application describes embodiments having specific structural features and/or methodological acts, it is to be understood that the claims are not necessarily limited to the specific features or acts described. Rather, the specific features and acts are merely illustrative some embodiments that fall within the scope of the claims of the application.

1.-20. (canceled)

21. A method of manufacturing a 3-dimensional NAND (3D-NAND) memory device, the method comprising:
depositing a plurality of alternating first and second layers to form a stack, wherein the first layers comprising a first material and the second layers comprising a second material;
forming a plurality of grooves comprising the first material in the stack, the grooves extending along a wordline direction of the 3D-NAND memory device and dividing at least some of the second layers into strips extending along the wordline direction;
etching a plurality of channel holes in the stack, each channel hole overlapping one of the grooves and being wider than the one of the grooves in a bitline direction orthogonal to the wordline direction; and
depositing a memory layer and a channel layer into the channel holes to form vertical NAND strings.

22. The method of claim 21, wherein forming plurality of grooves comprises defining a gap region between two adjacent grooves substantially in alignment along the wordline direction.

23. The method of claim 22, wherein the channel holes etched in the stack are not overlapping the gap region.

24. The method of claim 22, further comprising:
etching a plurality of separation trenches in the stack, the separation trenches extending along the wordline direction;
selectively removing the second material of the second layers from exposed sidewalls of the second layers in the separation trenches;
depositing gate metal into spaces revealed by the removed second material, wherein the gap region providing a path for removing the second material and depositing the gate metal;
removing materials left in the separation trenches; and
filling the separation trenches with a dielectric material.

25. The method of claim 21, further comprising:
forming a staircase region on at least one side of the stack, wherein the plurality of grooves extending into the staircase region.

26. The method of claim 25, wherein:
at least one of the grooves only extends partially into the staircase region;
at least one second layer at a bottom of the stack has a first portion and a second portion on opposite sides of at least one of the grooves; and
the first and second portions are connected through remaining portion of the at least one second layer in the staircase region.

27. The method of claim 21, wherein:
the stack has a first height; and
at least one of the grooves has a second height less than the first height such that at least one of the second layers at a bottom of the stack not divided by at least one of the grooves.

28. The method of claim 21, wherein the channel holes are arranged in a staggered manner.

29. The method of claim 21, wherein the memory layer comprises a charge storage layer, a blocking dielectric between a channel hole sidewall and the charge storage layer, and a tunneling dielectric between the charge storage layer and the channel layer.

30. The method of claim 29, wherein the charge storage layer comprises a charge trapping layer.

31. The method of claim 29, wherein the charge storage layer comprises floating gates.

32. The method of claim 31, wherein the channel layer comprises polycrystalline silicon or silicon germanium.

33.-35. (canceled)

36. A method of manufacturing a U-shape NAND string for a 3-dimensional NAND (3D-NAND) memory device, the method comprising:
providing a substrate having a pipe connection;
depositing a plurality of alternating first and second layers to form a stack, wherein the first layers comprising a first material and the second layers comprising a second material;
forming first and second grooves comprising the first material in the stack, the first and second grooves extending along a wordline direction of the 3D-NAND memory device;
etching first and second channel holes in the stack to partially expose the pipe connection in the substrate, wherein the first channel hole overlapping the first groove and being wider than the first groove in a bitline direction orthogonal to the wordline direction, and wherein the second channel hole overlapping the second groove and being wider than the second groove in the bitline direction; and
depositing a memory layer and a channel layer into the first and second channel holes to form the U-shape NAND string.

37. The method of claim 36, further comprising:
etching first, second, and third separation trenches in the stack, the first, second, and third separation trenches extending along the wordline direction, wherein first groove located between the first and second separation trenches, the second separation trench located between the first and second grooves, and the second groove located between the second and third separation trenches; and
filling the first and second separation trenches with a dielectric material.

38. The method of claim 36, further comprising:
forming a staircase region on at least one side of the stack, wherein the first and second grooves extending into the staircase region.

39. The method of claim 38, wherein:
at least one of the grooves only extends partially into the staircase region;
at least one second layer at a bottom of the stack has a first portion and a second portion on opposite sides of at least one of the grooves; and
the first and second portions are connected through remaining portions of the at least one second layer in the staircase region.

40. The method of claim 36, wherein the second material is doped polysilicon.

41. The method of claim 36, wherein the first material is silicon oxide.

42. The method of claim 36, wherein the memory layer comprises a charge storage layer, a blocking dielectric between the second material and the charge storage layer, and a tunneling dielectric between the charge storage layer and the channel layer.

43. The method of claim 42, wherein the charge storage layer comprises a charge trapping layer.

44. The method of claim 42, wherein the charge storage layer comprises floating gates.
